(19) United States
(12) Patent Application Publication
(10) Pub. No.: US 2012/0007235 A1
(43) Pub. Date: Jan. 12, 2012

(54) Chip Fanning Out Method and Chip-on-Film Device

(76) Inventors: Chao-Chih Hsiao, Taipei City (TW); Po-Ching Li, Hsinchu City (TW)

(21) Appl. No.: 13/106,879

(22) Filed: May 13, 2011

Related U.S. Application Data
(60) Provisional application No. 61/362,678, filed on Jul. 8, 2010.

(30) Foreign Application Priority Data
Dec. 8, 2010 (TW) 099142803

(51) Int. Cl. H01L 23/498; H01L 21/50

(52) U.S. Cl. 257/737; 438/106; 257/E21.499; 257/E23.068

(57) ABSTRACT

A chip fanning out method is disclosed. The chip fanning out method includes mounting a chip on a film, forming a plurality of outer lead bonds spatially arranged in a bump correspondence order on the film, forming a plurality of bumps spatially arranged in a bump arrangement order on the chip, and forming a plurality of wires to connect the plurality of outer lead bonds to the plurality of bumps according to the bump correspondence order, wherein the bump correspondence order is different from the bump arrangement order.

### CROSS REFERENCE TO RELATED APPLICATIONS

This application claims the benefit of U.S. Provisional Application No. 61/362,678, filed on 2010, Jul. 08 and entitled “Fanning out methods for Chip on Film Packaging Process”, the contents of which are incorporated herein by reference.

### BACKGROUND OF THE INVENTION

1. Field of the Invention

The present invention is related to a chip fanning out method and chip-on-film device, and more particularly, to a chip fanning out method and chip-on-film device with different arrangement orders for outer lead bonds and bumps.

2. Description of the Prior Art

With advances in circuit manufacturing technology, integrated circuit (IC) chips are not only mounted on printed circuit boards (PCBs) but films as well. Such packaging technology is named as chip-on-film (COF) packaging technology.

Please refer to FIG. 1, which is a schematic diagram of a fanning out layout of a COF package of the prior art. In FIG. 1, bumps B1-BN of a chip 100 are connected to outer lead bonds (OLBs) O1-ON via wires L1-LN of a film 110. The OLBs O1-ON may be connected to peripheral hardware circuits, such as a conventional PCB, liquid crystal display (LCD) panel, etc. Since the wires L1-LN can be only fanned out on the single-layer film 110, arrangement orders of the bumps B1-BN have to be consistent to those of the OLBs O1-ON so as to facilitate laying out the circuit. In FIG. 1, to maintain signal transmission quality, distances between the wires and bending angles θ of the wires are strictly limited. That is, if the bending angles θ are less than a threshold angle, the wires do not conform to system application manufacturers' requirements, and cannot connect the bumps to the OLBs. That is, the bumps B1-BN have to be properly allocated to fan out all the bumps B1-BN to the OLBs. In addition, a size of the film 110 and a position of the chip 100 on the film 110 are strictly limited as well. For that reason, merely a part of the bumps can be fanned out to the OLBs.

In order to fan out more bumps, area of the chip 100 is expanded, such as a chip 200 illustrated in FIG. 2. As a result, allocation range for the bumps increases, allowing a greater bending angle θ which conforms to hardware requirements. Other than increasing the chip area, positions of the bumps and a number of bumps located in one side of the chip are also adjusted to overcome limitations caused by the bending angles θ. For example, bumps with small bending angles are moved to other sides.

However, increasing the chip area and adjusting the bump positions both involve redesign for inner IC layout, which is disadvantageous to chip size and design cost.

Therefore, overcoming the limitations caused by the bending angles on the film to fanning out the chip in a more economic way has been a main focus of the industry.

### SUMMARY OF THE INVENTION

Therefore, a chip fanning out method and related chip-on-film device are provided herein, which can significantly increase fanned out bumps of a chip and reduce a cost of the chip.

A chip fanning out method is disclosed, comprising mounting a chip on a film, forming a plurality of outer lead bonds (OLBs) on the film, wherein the plurality of OLBs are spatially arranged in a bump correspondence order, forming a plurality of bumps on the chip, wherein the plurality of bumps are spatially arranged in a bump arrangement order, and forming a plurality of wires to connect the plurality of OLBs with the plurality of bumps according to the bump correspondence order, wherein the bump correspondence order is different from the bump arrangement order, and the plurality of wires are not overlapped.

A chip-on-film (COF) device is further disclosed, comprising a film comprising a plurality of outer lead bonds (OLBs) spatially arranged in a bump correspondence order, a chip comprising a plurality of bumps spatially arranged in an bump arrangement order, and a plurality of wires for connecting the plurality of OLBs and the plurality of bumps according to the bump correspondence order, wherein the bump correspondence order is different from the bump arrangement order, and the plurality of wires are not overlapped.

A chip fanning out method is further disclosed, comprising mounting a chip on a film, forming a plurality of outer lead bonds (OLBs) on the film, forming a plurality of bumps on the chip, and forming a plurality of wires to respectively connect the plurality of OLBs with the plurality of bumps, wherein at least one of the plurality of wires is utilized for connecting at least one of the plurality of bumps and at least one of the plurality of OLBs not correspondent in space.

A chip-on-film (COF) device is further disclosed, comprising a film comprising a plurality of outer lead bonds (OLBs), a chip comprising a plurality of bumps, and a plurality of wires for respectively connecting the plurality of OLBs and the plurality of bumps, wherein at least one of the plurality of bumps is connected with at least one of the plurality of OLBs not correspondent in space.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a fanning out layout of a COF package of the prior art.

FIG. 2 is a schematic diagram of another fanning out layout of the COF package shown in FIG. 1.

FIG. 3 to FIG. 7 are schematic diagrams of COF devices according to different embodiments.

FIG. 8 is a schematic diagram of a chip fanning out process according to an embodiment.

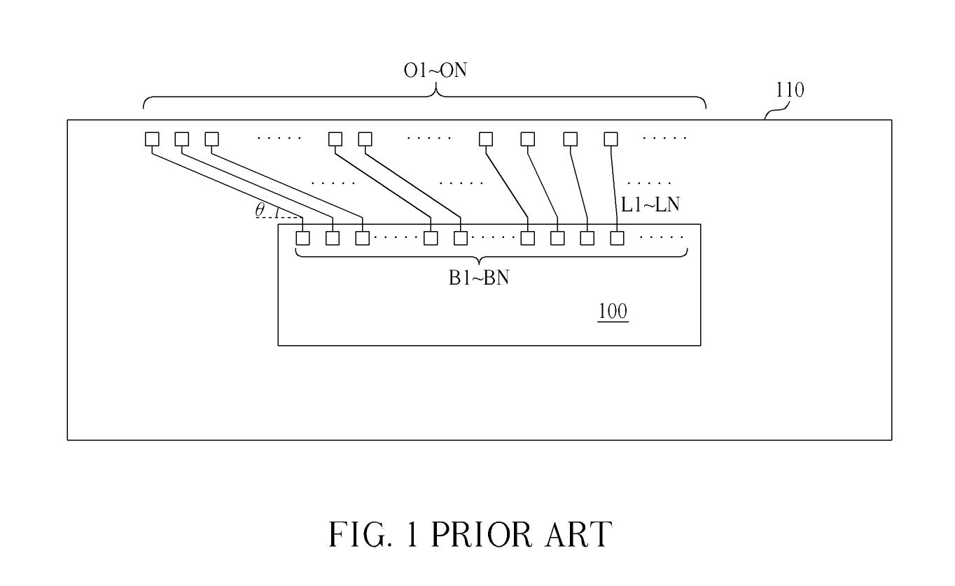

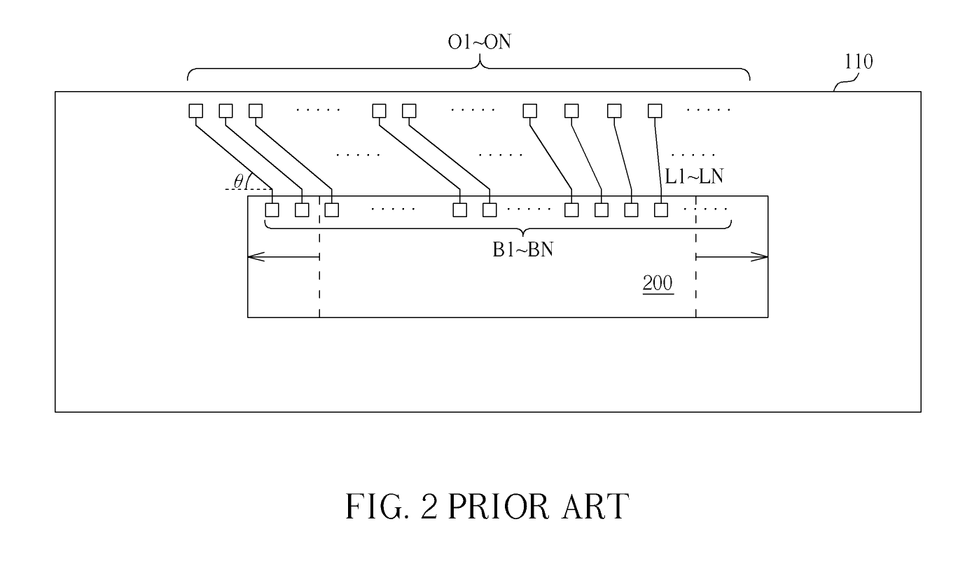

### DETAILED DESCRIPTION

Different from the prior art in which outer lead bonds (OLBs) are connected with bumps according to a bump arrangement order, the OLBs in the following embodiments are connected with the bumps according to an order other than the bump arrangement order. That is, connection corresponding relationship between the OLBs and the bumps are different from spatial corresponding relationship therebetween. More specifically, the OLBs are spatially arranged in a bump correspondence order, and the bumps are spatially arranged in a bump arrangement order, which is different from the bump correspondence order.

In the following embodiments, the bump correspondence order and the bump arrangement order are no longer identical to overcome troublesome caused by the bending angle limitation in the prior art and increase design flexibility of chip fanning out. As a result, cost for fanning out the chip can be significantly reduced without expanding the chip area. Details are described in the following embodiments.

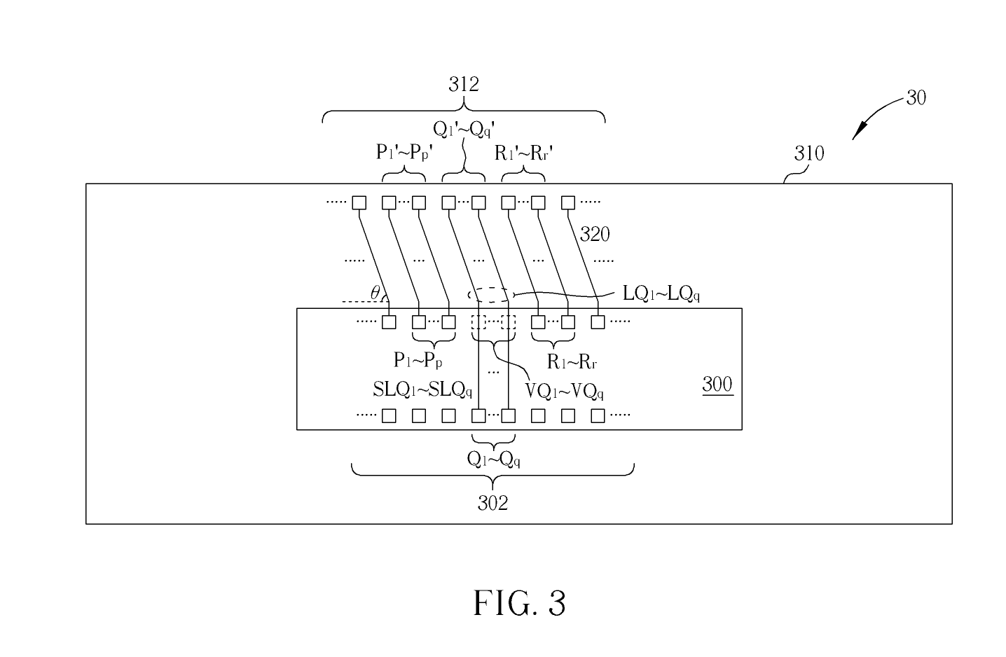

Please refer to FIG. 3, which is a schematic diagram of a chip-on-film (COF) device 30 according to an embodiment. The COF 30 includes a film 310, a chip 300 and plural wires 320. The film 310 includes OLBs 312 utilized for connecting external hardware devices, such as a printed circuit board (PCB), a liquid crystal display (LCD) panel, etc. The chip 300, mounted on the film 310, includes bumps 302 which are connected via the wires 320 to the OLBs 312. Preferably, the wires 320 are not mutually overlapped.

According to the embodiment shown in FIG. 3, bumps Q₁-Q_{q} located in a bottom side of the chip 300 are connected to OLBs Q₁′-Q_{q}′ near an upper side of the chip 300 instead of OLBs near the bottom side. More specifically in terms of spatial corresponding relationship, the bumps 302 are spatially arranged as . . . P₁-Pₚ→R₁-Rᵣ→Q₁-Q_{q} . . . , but the OLBs 312 are spatially arranged as . . . P₁-Pₚ→Q₁′-Q_{q}′→R₁′-Rᵣ′ . . . . That is, the bumps connected to the OLBs are spatially arranged d as . . . →P₁˜-Pₚ→Q₁˜Q_{q}→R₁˜Rᵣ. The bump arrangement order “. . . P₁-Pₚ→R₁-Rᵣ→Q₁-Q_{q}→ . . . ” is different from the bump correspondence order “. . . →P₁′-Pₚ′Q₁′-Q_{q}′→R₁′-Rᵣ′→ . . . ”. In other words, the OLBs 312 are not connected to the bumps 302 according to the bump arrangement order “. . . P₁˜Pₚ→R₁˜Rᵣ→Q₁˜Q_{q} . . . ”.

As a result, arrangement orders of the OLBs 312 and the bumps 302 are no longer to be restricted to be identical in the COF device 30, and therefore the layout can be designed with more flexibility. Moreover, the bending angles θ of the wires L1-LM can be greater than a threshold angle specified in hardware limitations without modifying area or position of the chip 300. That is, the chip fanning out problem caused by the bending angles θ is solved in the circuit layout shown in FIG. 3.

In FIG. 3, in order to achieve different bump arrangement order and bump correspondence order on a premise that the wires 320 are not mutually overlapped with each other, the wires LQ₁-LQ_{q} corresponding to the bumps Q₁-Q_{q} are first extended inwardly to the chip 300 instead of being directly extended outwardly against the chip 300 like the other wires . In other words, the wires LQ₁-LQ_{q} include extra sections SLQ₁-SLQ_{q} routed around the central bottom area of the chip 300 surrounded by the bumps 302 such that they are extended outwardly via virtual bumps VQ₁-VQ_{q} against the chip 300. Note that, the virtual bumps VQ₁-VQ_{q} are not employed for receiving or outputting any chip signal but merely for fixing the wires. In alternative embodiments, the virtual bumps represented by dotted squares may not be implemented and only the occupied area of the dotted squares are provided. In such a situation, the wires LQ1-LQq directly connect the bumps Q₁-Q_{q} with the OLBs Q₁′-LQ_{q}′.

In short, through routing the wires LQ₁-LQ_{q} under the chip 300, the bump arrangement order and the bump correspondence order can be different without affecting functions of the chip 300. Note that, even though the wires LQ₁-LQ_{q} are exemplarily illustrated as routed around a central bottom area of the chip 300 in FIG. 3, the wires LQ₁-LQ_{q} can be also routed around a top area, a side area or any other area of chip 300 in other embodiments, as long as the routing allows different bump arrangement order and bump correspondence order.

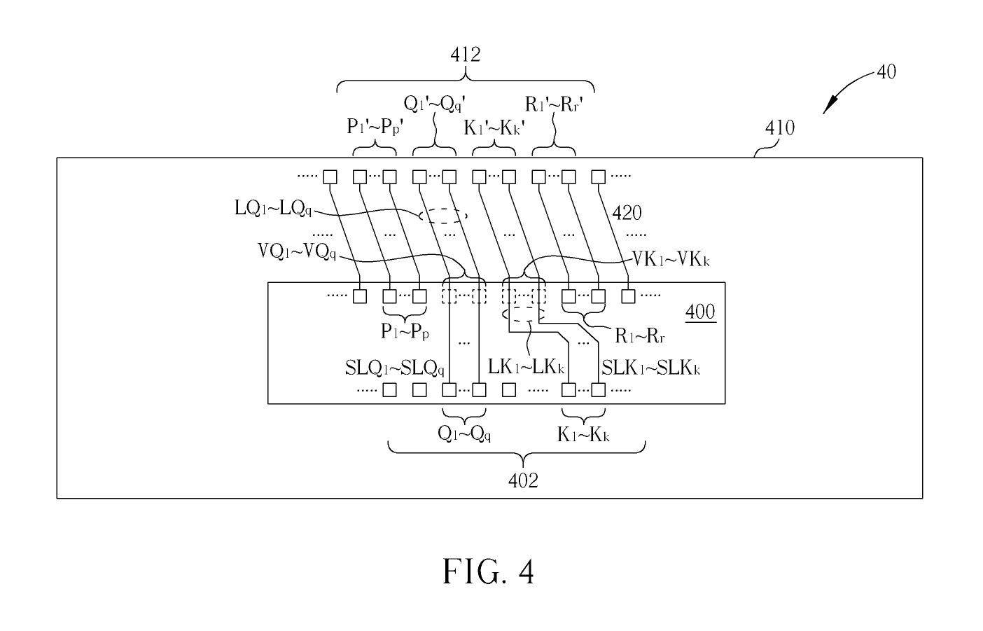

The COF device 30 of FIG. 3 illustrates an embodiment for a simplest routing of only one set of wires. In fact, plural sets of wires can be routed similarly, as illustrated in FIG. 4, which is a schematic diagram of a COF device according to another embodiment. In the COF device 40 shown in FIG. 4, two sets or wires LQ₁-LQ_{q}, LK₁-LKₖ respectively connect bumps Q₁-Q_{q}, K₁-Kₖ on one side (e.g. , bottom side) of a chip 400 with corresponding OLBs Q₁′-Q_{q}′, K₁′-Kₖ′ close to another side (e.g., top side) of the chip 400. As a result, OLBs 412 are spatially arranged as “. . . P₁′-Pₚ′→Q₁, ˜Q_{q}→K₁′˜Kₖ′→R₁′˜Rᵣ′→ . . . ”, which is different from an arrangement order of bumps 402, i.e. “. . . P₁˜Pₚ→R₁˜Rᵣ→K₁˜Kₖ→Q₁˜Q_{q} . . . ”. Similarly, the two sets of wires LQ₁-LQ_{q}, LK₁-LKₖ are not directly extended outwardly against the chip 400. Instead, they are first extended inwardly to the chip 400 to include extra sections SLQ₁-SLQ_{q}, SLK₁-SLK, and then extended outwardly via virtual bumps VQ₁-VQ_{q} against the chip 400.

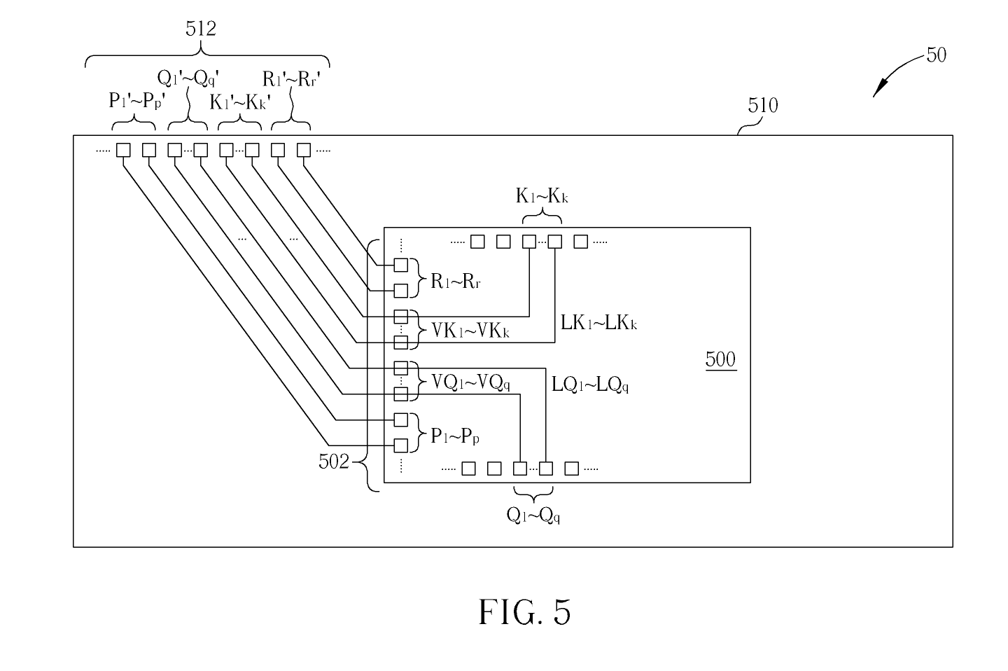

Other than connecting the bumps located on two opposite sides of the chip, the wires can further connect bumps located on two adjacent sides of a chip, as illustrated in FIG. 5, which is a schematic diagram of a COF device according to another embodiment. In the COF device 50 shown in FIG. 5, wires LK₁-LKₖ, LQ₁-LQ_{q} respectively connect virtual bumps VK₁-VKₖ, VQ₁-VQ_{q} located on different long sides with bumps K₁-Kₖ, Q₁-Q_{q} located on different short sides so as to further connect to OLBs K₁′-Kₖ, Q₁′-Q_{q}′ in shorter paths. As a result, OLBs 512 are spatially arranged as “. . . →P₁′-Pₚ′→Q₁-Q_{q}′→K₁-Kₖ′→R₁′-Rᵣ′→ . . . ”, which is different from an arrangement order of bumps 502, i.e. “. . . P₁-Pₚ→R₁-Rᵣ→K₁-Kₖ→Q₁-Q_{q}→ . . . ”. Similarly, the two sets of wires LQ₁-LQ_{q}, LK₁-LKₖ are not directly extended outwardly against the chip 500. Instead, they are first extended inwardly to the chip 500 to include extra sections SLQ₁-SLQ_{q}, SLK₁-SLKₖ, and then extended outwardly against the chip 500 via virtual bumps VQ₁-VQ_{q}, VK₁-VK.

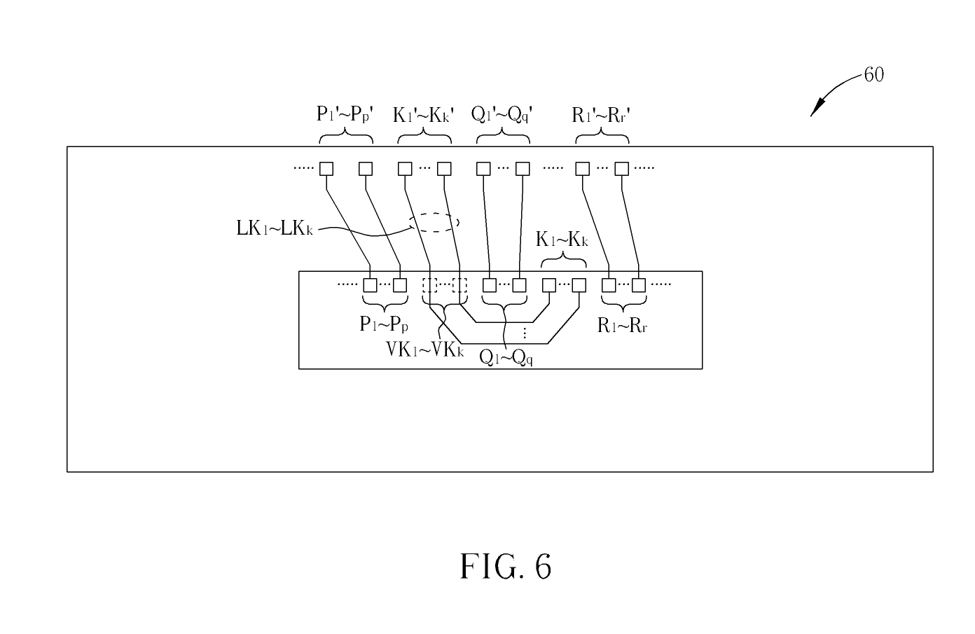

In addition, the novelty featuring the inconsistent bump correspondence order and bump arrangement order can further be applied to bumps located on the same side of a chip 600, as illustrated in FIG. 6. In a COF device 60 shown in FIG. 6, bumps K₁-Kᵣ, Q₁-Q_{q} are respectively connected to farther OLBs K₁′-Kᵣ′, Q₁′-Q_{q}′ instead of the closer OLBs Q₁′-Q_{q}′, K₁′-Kₖ′. More specifically, in space, the bump correspondence order is “. . . →P₁′-Pₚ′→K₁′-Kₖ′→Q₁′-Q_{q}′→R₁′-Rᵣ′→ . . . ”, which is different from the bump arrangement order, i.e. “. . . →P₁-Pₚ→Q₁-Q_{q}→K₁-Kₖ→R₁-Rᵣ→ . . . ”. Similarly, wires LK₁-LK are not directly extended outwardly. Instead, they are first extended inwardly to the chip, and then extended outwardly against the chip via virtual bumps VK₁-VKᵣ located on the same side.

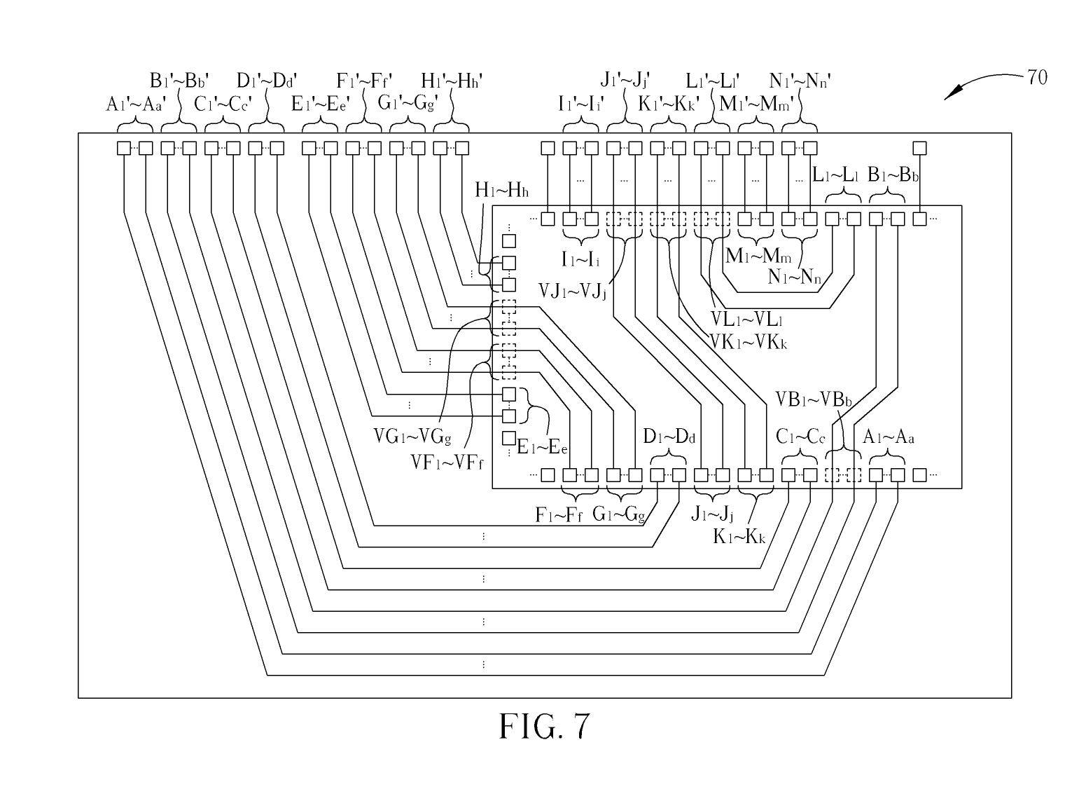

Furthermore, wire route methods illustrated from FIG. 3 to FIG. 6 can be realized in any combinations. For example, the wire route methods are combined and reused in a COF device 70 shown in FIG. 7. In this embodiment, the bump correspondence order is “A₁′-Aa′→B₁′-B_{b}′→C₁-C_{c}′→D₁′-D_{d}′→E₁′-Eₑ′→F₁′-F_{f}′→G₁′-G_{g}′→H₁′-Hₕ′→I₁′-Iᵢ′-→J₁′-Jⱼ′→K₁′-Kₖ′→L₁′-L₁′→M₁′-Mₘ′→N₁′-Nₙ′→ . . . ”, which is different from the bump arrangement order “A₁-Aₐ→C₁-C_{c}→K₁-Kₖ →J₁-Jⱼ→D₁-D_{d}→G₁-G_{g}→F₁-F_{f}→E₁-Eₑ→H₁-Hₕ→I₁-Iᵢ→M₁-Mₘ→N₁-Nₙ→L₁-Lₗ→B₁-B_{b}→ . . . ”. As a result, the chip can be more economically fanned out while conform to hardware limitations.

Note that, all the wires shown from FIG. 3 to FIG. 7 can conform to a limitation that bending angles of the wires are greater than a threshold angle on the films. In addition, wires can be routed further around a top area, a side area or any other area of the chip as long as the bump arrangement order and the bump correspondence order are different. Additionally, the bumps employed with the fanning out method can be any type, such as a power bump for receiving power, an input bump for receiving signals, an output bump for transmitting signals, etc.

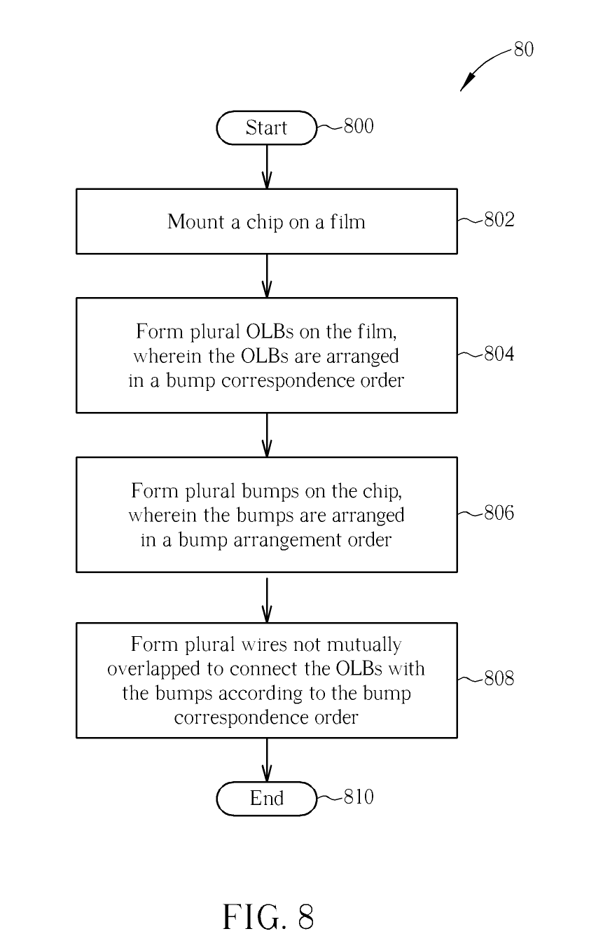

The wire layout operations of the COF devices shown from FIG. 3 to FIG. 7 can be summarized into a chip fanning out process 80, as illustrated in FIG. 8. The chip fanning out process 80 includes the following steps:

Step 800: Start.

Step 802: Mount a chip on a film.

Step 804: Form plural OLBs on the film, wherein the OLBs are spatially arranged in a bump correspondence order.

Step 806: Form plural bumps on the chip, wherein the bumps are spatially arranged in a bump arrangement order.

Step 808: Form plural wires not mutually overlapped to connect the OLBs with the bumps according to the bump correspondence order.

Step 810: End.

Similarly, the bump correspondence order is different from the bump arrangement order. Details of the chip fanning out process 80 can be referred in the above, and are not narrated herein.

In the prior art, since the bump correspondence order has to be identical to the bump arrangement order, wire fanning out layout is limited by the chip position, the chip size and the film size. If the bumps are numerous, the bending angles θ of the wires are compressed to be smaller than the threshold angle, thus not conforming to standards specified by chip manufacturers. Even if the chip area is increased or the bumps position are adjusted to increase the bending angles θ, layout of the integrated circuit has to be redesigned, which is disadvantageous to the chip size and the chip cost. In comparison, the corresponding relationship between the OLBs and the bumps are modified in above embodiments to overcome the bending angle and other hardware limitations. Through routing a part of the wires under, over or around the chip, the wires can be spatially arranged with more flexibility, and the chip can be fanned out in a more economic and convenient layout.

To sum up, through modification to the corresponding relationship between the OLBs and the bumps, the bending angle and other hardware limitations can be overcome, and the chip can be fanned out in a more economic, convenient and flexible layout accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A chip fanning out method comprising:
mounting a chip on a film;
forming a plurality of outer lead bonds (OLBs) on the film, wherein the plurality of OLBs are spatially arranged in a bump correspondence order;
forming a plurality of bumps on the chip, wherein the plurality of bumps are spatially arranged in a bump arrangement order; and
forming a plurality of wires to connect the plurality of OLBs with the plurality of bumps according to the bump correspondence order;
wherein the bump correspondence order is different from the bump arrangement order, and the plurality of wires are not mutually overlapped.

2. The chip fanning out method of claim 1 further comprising:
forming one or more virtual bumps on the chip,
wherein forming the plurality of wires comprises forming one or more of the plurality of wires to pass through the one or more virtual bumps.

3. The chip fanning out method of claim 1, wherein at least one of the plurality of wires is extended inwardly to the chip and then extended outwardly against the chip.

4. The chip fanning out method of claim 1, wherein at least one of the plurality of wires is routed around a bottom area, a top area or a side area of the chip.

5. The chip fanning out method of claim 1, wherein a bending angle of each of the plurality of wires is greater than a threshold angle.

6. The chip fanning out method of claim 1, wherein each of the plurality of bumps is a power bump, an input bump or an output bump.

7. The chip fanning out method of claim 1, wherein at least one of the plurality of bumps near a first side of the chip is connected with at least one of the plurality of OLBs that is near a second side of the chip.

8. The chip fanning out method of claim 1, wherein at least one of the plurality of bumps near a first side of the chip is connected with at least one of the plurality of OLBs that is near a first side of the chip and not corresponding to the at least one bump in space.

9. A chip-on-film (COF) device comprising:
a film, comprising a plurality of outer lead bonds (OLBs) spatially arranged in a bump correspondence order;
a chip, comprising a plurality of bumps spatially arranged in an bump arrangement order; and
a plurality of wires, for connecting the plurality of OLBs to the plurality of bumps according to the bump correspondence order;
wherein the bump correspondence order is different from the bump arrangement order, and the plurality of wires are not mutually overlapped.

10. The COF device of claim 9, wherein the chip further comprises one or more virtual bumps on the chip through which one or more of the plurality of wires are routed to pass.

11. The COF device of claim 9, wherein at least one of the plurality of wires is extended inwardly to the chip and then extended outwardly against the chip.

12. The COF device of claim 9, wherein at least one of the plurality of wires is routed around a bottom area, a top area, or a side area of the chip.

13. The COF device of claim 9, wherein a bending angle of each of the plurality of wires is greater than a threshold angle.

14. The COF device of claim 9, wherein each of the plurality of bumps is a power bump, an input bump or an output bump.

15. The COF device of claim 9, wherein at least one of the plurality of bumps near a first side of the chip is connected with at least one of the plurality of OLBs that is near a second side of the chip.

16. The COF device of claim 9, wherein at least one of the plurality of bumps near a first side of the chip is connected with at least one of the plurality of OLBs that is near a first side of the chip and not corresponding to the at least one bump in space.

17. A chip fanning out method comprising:
mounting a chip on a film;
forming a plurality of outer lead bonds (OLBs) on the film;
forming a plurality of bumps on the chip; and
forming a plurality of wires to respectively connect the plurality of OLBs with the plurality of bumps, wherein at least one of the plurality of wires connects at least one of the plurality of bumps to at least one of the plurality of OLBs that is not corresponding to the at least one bump in space.

18. A chip-on-film (COF) device comprising:
a film, comprising a plurality of outer lead bonds (OLBs);
a chip, comprising a plurality of bumps; and
a plurality of wires, for respectively connecting the plurality of OLBs and the plurality of bumps;
wherein at least one of the plurality of bumps is connected with at least one of the plurality of OLBs that is not corresponding to the at least one bump in space.
